(19) United States
(12) Patent Application Publication
(10) Pub. No.: US 2007/0063317 A1
(43) Pub. Date: Mar. 22, 2007

(54) Overlay key, method of forming the overlay key, semiconductor device including the overlay key and method of manufacturing the semiconductor device

(75) Inventors: Dae-Joung Kim, Suwon-si (KR); Dae-Youp Lee, Gunpo-si (KR); Ji-Yong You, Suwon-si (KR); Chun-Suk Suh, Yongin-si (KR); Do-Yul Yoo, Seongnam-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/472,376

(22) Filed: Jun. 22, 2006

(30) Foreign Application Priority Data
Jun. 24, 2005 (KR) 2005-54799

(51) Int. Cl. H01L 29/06; H01L 23/48; H01L 23/52; H01L 29/40; H01L 21/336; H01L 21/00

(52) U.S. Cl. 257/622; 257/774; 438/460; 438/261

(57) ABSTRACT

An overlay key formed in a scribe lane and used to align a circuit pattern may include a lower overlay mark formed on a metal silicide layer directly in contact with a silicon substrate. A method of forming an overlay key in a scribe lane may include providing a silicon substrate, forming a metal silicide layer to be in direct contact with the silicon substrate, and forming a lower overlay mark on the metal silicide layer.

### PRIORITY CLAIM

A claim of priority is made under 35 USC § 119 to Korean Patent Application No. 2005-54799, filed on Jun. 24, 2005, the contents of which are herein incorporated by reference in their entirety.

### BACKGROUND OF THE INVENTION

1. Field of the Invention

Example embodiments of the present invention relate to an overlay key, a method of forming the overlay key, a semiconductor device formed using the overlay key, and a method of manufacturing a semiconductor device using the overlay key. More particularly, example embodiments of the present invention relate to an overlay key that is capable of more accurately calibrating an overlay degree by reducing an overlay variation, a method of forming the overlay key, a semiconductor device formed using the overlay key, and a method of manufacturing a semiconductor device.

2. Description of the Related Art

In general, to manufacture a semiconductor device, a unit process, for example, a deposition process, a photolithography process, an etching process, etc., may be repeatedly performed to form circuit patterns.

A thin layer may be converted into a circuit pattern by a photolithography process and an etching process. For example, a photoresist film may be formed on a lower layer. Light may be irradiated onto the photoresist film through a reticle, which has a reticle pattern corresponding to a circuit pattern to be formed, to expose the photoresist film. The exposed photoresist film may be developed using a developing solution to form a photoresist pattern. The lower layer may be etched using the photoresist pattern as an etching mask to form the circuit pattern.

In forming the circuit pattern, it may be important to precisely align a circuit pattern with a lower pattern that may have been formed by a preceding process. To precisely align the circuit pattern with the lower pattern, the photoresist pattern used as the etching mask should be accurately positioned.

To accurately position the photoresist pattern, an overlay key may be formed on a scribe lane region of a semiconductor substrate. A scribe lane may be used as a cut line to divide the semiconductor substrate into a plurality of semiconductor chips. The overlay key may include a lower overlay mark formed on a lower pattern and an upper overlay mark corresponding to a photoresist pattern. Deviations between lateral portions, longitudinal portions, rotation, perpendicularity, etc., of the upper and lower overlay marks may be measured to determine an alignment of the photoresist pattern. When the alignment of the photoresist pattern is determined to be outside an acceptable range, an overlay compensation value may be obtained. The obtained overlay compensation value may be used as an overlay compensation value by an exposure apparatus when a proceeding exposure process is carried out.

As described above, to accurately calibrate an overlay key, it may be required to obtain image information of a lower overlay mark and an upper overlay mark. However, as semiconductor devices have become more integrated with complicated stack structures, a gap between the lower overlay mark and the upper overlay mark may be considerably large. Further, a lower layer under the lower overlay mark and an upper layer over the lower overlay mark may have an influence on the lower overlay mark. Thus, accurate image information of the lower overlay mark may not be obtained.

Furthermore, materials used as a thin layer of a semiconductor device, for example, metal, metal nitride, silicon nitride, etc., may have a large light absorption constant. Thus, when the materials having a large light absorption constant are formed under and over the lower overlay mark, substantial amount of lights emitted from an overlay calibrator may be absorbed by these materials, thus reducing the accuracy of image information of the lower overlay mark. Peripherals of the lower and upper overlay marks may look dark so that the lower overlay mark and the upper overlay mark may not be precisely distinguished from each other. As a result, the overlay calibration between the lower overlay mark and the upper overlay mark may not be accurate. Further, reproducibility of the overlay calibration may be lowered. These problems may cause an increase of overlay variation from wafer to wafer.

When an overlay calibration has a low accuracy, an additional process to correct overlay calibration problems may be performed. If the correction process is not performed, circuit pattern failures may be generated.

### SUMMARY OF THE INVENTION

Example embodiments of the present invention may provide an overlay key that is capable of more accurately calibrating an overlay degree by reducing an overlay variation.

In an example embodiment of the present invention, an overlay key formed in a scribe lane and used to align a circuit pattern may include a lower overlay mark formed on a metal silicide layer directly in contact with a silicon substrate.

In an example embodiment of the present invention, a method of forming an overlay key in a scribe lane may include providing a silicon substrate, forming a metal silicide layer to be in direct contact with the silicon substrate, and forming a lower overlay mark on the metal silicide layer. In another example embodiment of the present invention, a semiconductor device may include a semiconductor structure formed on a chip region, the semiconductor structure including a transistor having a first metal silicide layer, an insulation interlayer, and an upper wiring, and a lower overlay mark formed on a scribe lane region, the lower overlay mark formed on a second metal silicide layer directly in contact with a silicon substrate. In another example embodiment of the present invention, a method of manufacturing a semiconductor device may include forming a transistor having a first metal silicide layer on a silicon substrate in a chip region, forming a second metal silicide layer to be directly in contact with the silicon substrate in a scribe lane region, forming an insulation interlayer on the transistor, partially etching the insulation interlayer in the scribe lane region to form a trench-shaped lower overlay mark, forming a conductive layer on the chip region and the scribe lane region, forming a photoresist pattern on the conductive layer in the chip region, and an upper overlay mark on the silicon substrate in the scribe lane region, and partially etching the conductive layer using the photoresist pattern as an etching mask to form an upper wiring.

### BRIEF DESCRIPTION OF THE DRAWINGS

Example embodiments of the present invention may become readily apparent by reference to the following detailed description when considered in conjunction with the accompanying drawings wherein:

FIG. 1 is a cross sectional view illustrating an overlay key in accordance with an example embodiment of the present invention;

FIGS. 2 to 4 are cross sectional views illustrating a method of forming the overlay key illustrated FIG. 1;

FIG. 5 is a cross sectional view illustrating a semiconductor device formed using the overlay key illustrated in FIG. 1;

FIGS. 6 to 14 are cross sectional views illustrating a method of manufacturing the semiconductor device in illustrated in FIG. 5;

FIG. 15 is a plan view illustrating an overlay key illustrated in FIG. 14;

FIG. 16 is a flow chart illustrating a method of calibrating the overlay key illustrated in FIG. 15;

FIG. 17 is a cross sectional view illustrating an overlay key in accordance with Comparative Example 1;

FIG. 18 a graph illustrating light reflexibility of the overlay key in illustrated FIG. 17 based on thicknesses of a silicon oxide layer and a silicon nitride layer;

FIG. 19 is a graph illustrating light reflexibility of the overlay key illustrated in FIG. 1 by a refractive index and a light absorption constant of cobalt;

FIG. 20 is a scanning electron microscope (SEM) image illustrating the overlay key illustrated in FIG. 17; and

FIG. 21 is an SEM image illustrating the overlay key illustrated in FIG. 1.

### DESCRIPTION OF EXAMPLE EMBODIMENTS OF THE INVENTION

Example embodiments of the present invention may be described more fully hereinafter with reference to the accompanying drawings, in which example embodiments of the present invention are shown. The present invention may, however, be embodied in many different forms and should not be construed as limited to the example embodiments set forth herein. Rather, these example embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments of the present invention are described herein with reference to cross-section illustrations that are schematic illustrations of idealized embodiments (and intermediate structures) of the present invention. As such, variations from the shapes of the illustrations as a result, for example, of manufacturing techniques and/or tolerances, are to be expected. Thus, example embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention. Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

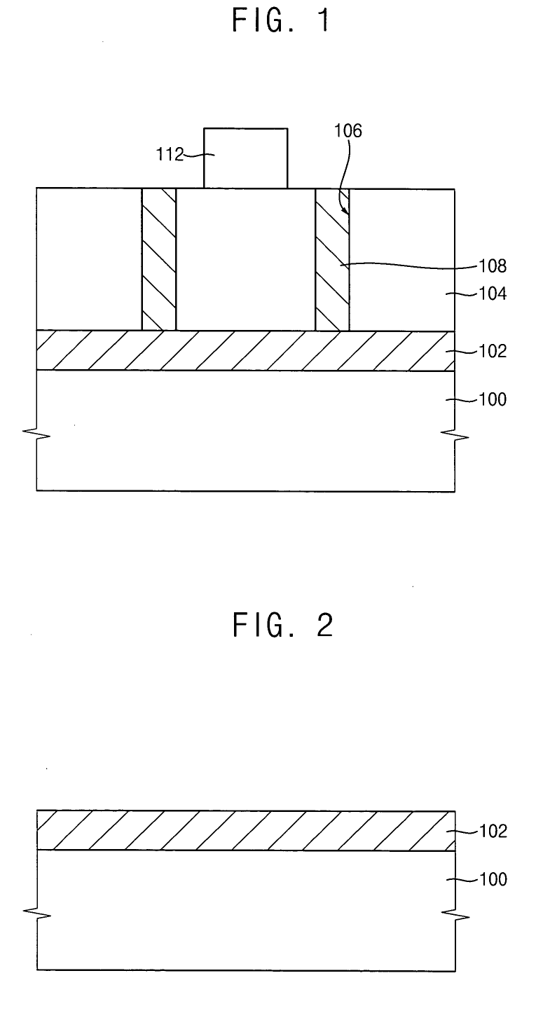

FIG. 1 is a cross sectional view illustrating an overlay key in accordance with an example embodiment of the present invention.

Referring to FIG. 1, a silicon substrate 100 may be divided into a chip region and a scribe lane region. The chip region may correspond to a region where semiconductor devices are formed. The scribe lane region may correspond to a region that is cut to divide a silicon substrate 100 into semiconductor devices.

An overlay key is formed on the scribe lane region but not the chip region. FIG. 1 only illustrates the scribe lane region of a silicon substrate 100.

A metal silicide layer 102 may be formed on the silicon substrate 100 in the scribe lane region. Silicon in the silicon substrate 100 and metal may be reacted with each other to form the metal silicide layer 102. Examples of the metal silicide layer 102 may include a cobalt silicide layer, a tungsten silicide layer, a tantalum silicide layer, a titanium silicide layer, etc. Further, the metal silicide layer 102 may have a light reflexibility of about 8% to about 30%.

A layer having a high light absorption constant, for example, an oxide layer, a nitride layer, etc., should not be formed on the silicon substrate 100 in the scribe lane region. On the contrary, the metal silicide layer 102 having a relatively high light reflexibility may be formed on the silicon substrate 100 in the scribe lane region. Thus, the overlay key of example embodiment of the present invention may have a light reflexibility higher than a conventional overlay key.

An insulation interlayer 104 may be formed on the metal silicide layer 102. The insulation interlayer 104 may include a silicon oxide layer having a high light transmissivity.

A lower overlay mark 106 may be provided to the insulation interlayer 104. The lower overlay mark 106 may correspond to a trench that may be formed by partially etching the insulation interlayer 104. Further, the trench may have a box shape or a bar shape. Additionally, the trench may be filled with a filling material 108.

An upper overlay mark 112 may be formed on the insulation interlayer 104. The upper overlay mark 112 may correspond to a photoresist pattern. The upper overly mark 112 in the scribe lane region may be formed simultaneously with a photoresist pattern in the chip region. The upper overlay mark 112 may be used for determining whether the photoresist pattern in the chip region is normal or not. The upper overlay mark 112 may be positioned on a central portion of the insulation interlayer 104 enclosed by the lower overlay mark 106.

A layer (not shown) to be etched, which may be etched using a photoresist pattern as an etching mask, should not remain between the lower and upper overlay marks 106 and 112. If the layer still exits between the lower and upper overlay marks 106 and 112, an overlay calibration tool may not recognize the lower overlay mark 106. Therefore, before the photoresist pattern is formed, the layer in the scribe lane region must be removed.

According to an example embodiment of the present invention, a layer having a high light transmissivity, for example, a metal layer, a metal nitride layer, a silicon nitride layer, etc., may not be formed at a peripheral of an overlay key including lower and upper overlay marks 106 and 112. On the contrary, a metal silicide layer 102 having a relatively high light reflexibility may be formed at a peripheral of an overlay key. Thus, a light, which may be irradiated into a silicon substrate 100 from an overlay calibration tool, should not be absorbed in the metal silicide layer 102. Most of the light is reflected from the metal silicide layer 102 so that the reflected light may be received by the overlay calibration tool. As a result, accurate image information with respect to the overlay key may be obtained. An accurate overlay calibration may be carried out using image information so that overlay variation by individual silicon substrates may be reduced.

FIGS. 2 to 4 are cross sectional views illustrating a method of forming the overlay key illustrated in FIG. 1.

Referring to FIG. 2, a silicon substrate 100 may be divided into a chip region and a scribe lane region. An overlay key may be formed on a scribe lane region but not a chip region. Accordingly, FIG. 1 only illustrates the scribe lane region of the silicon substrate 100. Further, when lower layers are formed on the silicon substrate 100 in the scribe lane region, the lower layers may be removed.

A metal layer (not shown) may be formed on the silicon substrate 100. The metal layer may be converted into a metal silicide layer by well known silicidation process between silicon in the silicon substrate 100 and metal in the metal layer. Examples of the metal layer may include a cobalt layer, a tungsten layer, a tantalum layer, a titanium layer, etc. In the example embodiment of the present invention, the cobalt layer may be used as the metal layer.

The higher the metal silicide layer's light reflexibility is, the more accurate the overlay calibration may be. The light reflexibility of the metal silicide layer means the quality or capacity of reflexing light. When the cobalt layer is used as the metal layer, the light absorption constant of the cobalt layer may be about 2.5% to about 4% to improve the light reflexibility of the cobalt silicide layer.

The metal layer may be thermally treated. The silicon in the silicon substrate 100 and the metal in the metal layer may be reacted with each other to form the metal silicide layer 102. The thermal treatment may be carried out at least once. In addition, a capping layer (not shown) may be formed on the metal layer. The metal silicide layer 102 may directly contact with the silicon substrate 100 in the scribe lane region.

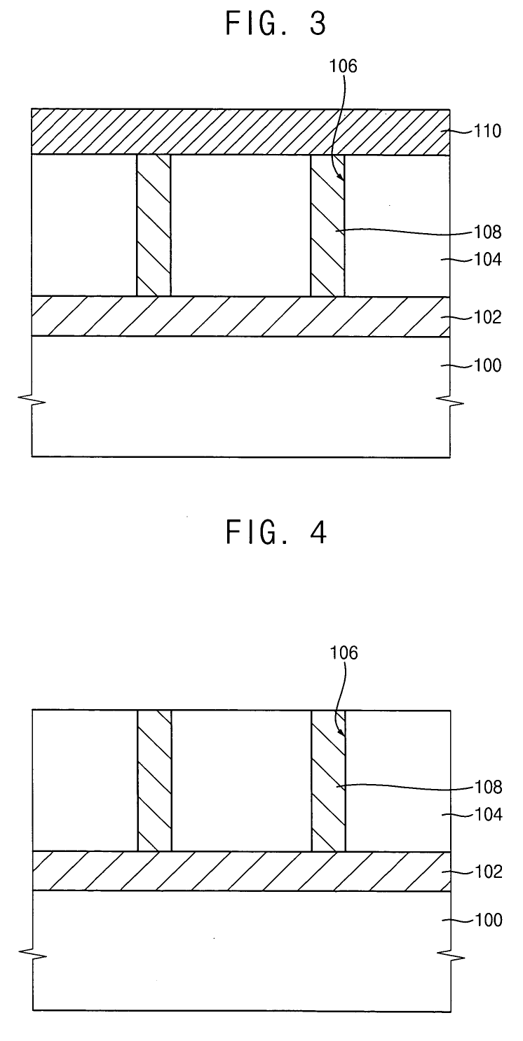

Referring to FIG. 3, an insulation interlayer 104 may be formed on the metal silicide layer 102. The insulation interlayer 104 may include a silicon oxide layer having a high light transmissivity.

The insulation interlayer 104 in the scribe lane region may be partially etched to form a trench corresponding to a lower overlay mark 106. The lower overlay mark 106 may have a box shape or a bar shape.

The formed trench may be filled with a filling material. For example, when a process to form a contact is performed in the chip region, a trench may be filled with a conductive layer.

A layer 110 to be etched may be formed on the insulation interlayer 106 having the lower overlay mark 106. Examples of the layer 110 may include a metal layer, a polysilicon layer, a silicon nitride layer, etc.

Referring to FIG. 4, the layer 110 in the scribe lane region may be removed. As a result, the layer 110 should not exist on the scribe lane region. Thus, since the layer 110 should be completely removed from the scribe lane region, light, which may be irradiated into the scribe lane region from an overlay calibration tool, may not be absorbed in the layer 110 so that accurate image information with respect to the overlay key may be obtained.

Referring back to FIG. 1, a photoresist film (not shown) may be formed on the insulation interlayer 104 having the lower overlay mark 106. The photoresist film may be exposed and developed to form a photoresist pattern corresponding to an upper overlay mark 112. The upper overlay mark 112 may be used to recognize whether the photoresist pattern in the chip region is normal or not. The upper overlay mark 112 may be positioned on a central portion of the insulation interlayer 104 enclosed by the lower overlay mark 106.

According to an example embodiment of the present invention, the overlay key used to accurately calibrate an overlay degree may be formed.

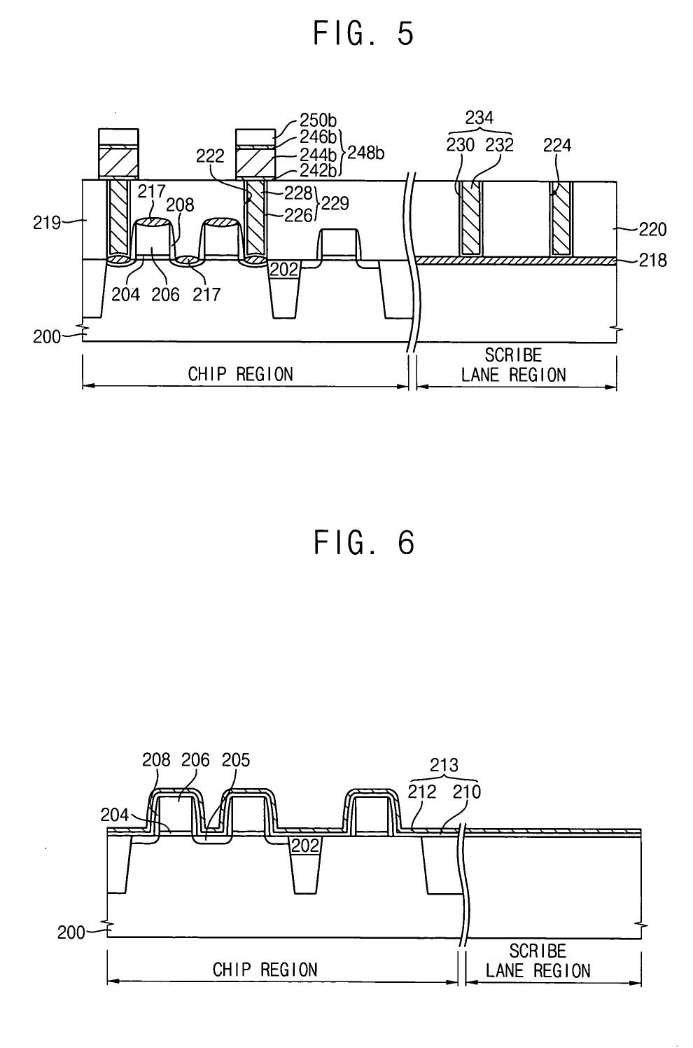

FIG. 5 is a cross sectional view illustrating a semiconductor device formed using the overlay key in FIG. 1 in accordance with an example embodiment of the present invention.

Referring to FIG. 5, a silicon substrate 200 may be divided into a chip region and a scribe lane region. The chip region corresponds to a region where semiconductor devices may be formed. The scribe lane region corresponds to a region that may be cut to divide the silicon substrate 200 into individual semiconductor devices.

A chip region of a silicon substrate 200 will be illustrated in detail. An isolation layer 202 may be formed in the silicon substrate 200 in the chip region to define an active region and an isolation region.

A transistor may be formed on the silicon substrate 200 in the chip region. The transistor may include a gate 215 having a first metal silicide layer pattern 217. The gate 215 may include a gate insulation layer 204, a polysilicon layer pattern 206, and the first metal silicide layer pattern 217. A spacer 208 including silicon nitride may be formed on a sidewall of the gate.

Source/drain regions 206 may be formed at portions of the silicon substrate 200 between two gates 215. In addition, the first metal silicide layer pattern 217 may be formed on the source/drain regions 216.

Examples of the first metal silicide layer pattern 217 may include a cobalt silicide layer, a tungsten silicide layer, a tantalum silicide layer, a titanium silicide layer, etc. In FIG. 5, a cobalt silicide layer may be used as the first metal silicide layer pattern 217.

A first insulation interlayer 219 may be formed on the silicon substrate 200 in the chip region to cover the transistor. The first insulation interlayer 219 may include a silicon oxide layer having a high light transmissivity.

A contact plug 229 may be formed in the first insulation interlayer 219. The contact plug 229 may be electrically connected to the source/drain regions 216. Examples of the contact plug 229 may include doped polysilicon, tungsten, aluminum, titanium, tantalun, titanium nitride, tantalum nitride, and a combination thereof. In FIG. 5, the contact plug 229 may include a first barrier metal layer 226 and a tungsten layer 228. The first barrier metal layer 226 may include a titanium/titanium nitride layer.

An upper wiring 248b may be formed on the first insulation interlayer 219. The upper wiring 248b may be electrically connected to the contact plug 229. Examples of the upper wiring 248b may include tungsten, aluminum, copper, titanium, tantalum, titanium nitride, tantalum nitride, and a combination thereof. In FIG. 5, the upper wiring 248b may include a sequentially stacked metal layer pattern 242b, an aluminum layer pattern 244b, and a third barrier metal layer pattern 246b. A hard mask layer pattern 250b may be formed on the upper wiring 248b.

Hereinafter, a scribe lane region of a silicon substrate 200 where an overlay key is formed will be illustrated in detail. The overlay key of the example embodiment of the present example may be used to align patterns during a photolithography process to form the upper wiring 248b.

A second metal silicide layer pattern 218 may cover the silicon substrate 200 in the scribe lane region. Silicon in the silicon substrate 200 and metal may be silicidated to form the second metal silicide layer pattern 218. The second metal silicide layer pattern 218 may include a material substantially identical to that of the first metal silicide layer pattern 217. Further, the second metal silicide layer pattern 218 may have a light reflexibility of about 8% to about 30%.

A second insulation interlayer 220 may be formed on the second metal silicide layer pattern 218. The second insulation interlayer 220 may include a material substantially identical to that of the first insulation interlayer 219.

A lower overlay mark 224 may be provided in the second insulation interlayer 220. The lower overlay mark 224 corresponds to a trench that may be formed by partially etching the second insulation interlayer 220. Further, the trench may have a box shape or a bar shape.

The lower overlay mark 224 may be filled with a conductive layer pattern 234. The conductive layer pattern 234 may include a material substantially identical to that of the contact plug 229. In an example embodiment of the present invention, the conductive layer pattern 234 may include a barrier metal layer 230 and a tungsten layer 232.

According to an example embodiment of the present invention, an upper overlay mark (not shown) corresponding to a photoresist pattern may be formed on a second insulation interlayer 220 having a lower overlay mark 224 so that an upper wiring 248b may be formed on an accurate position on a chip region.

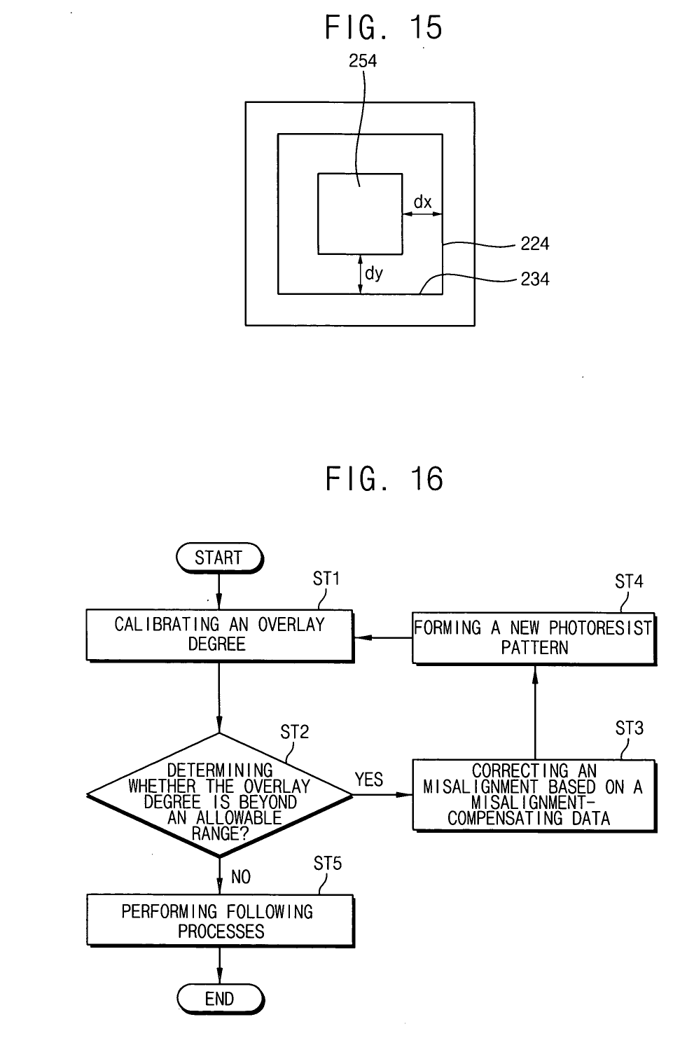

FIGS. 6 to 14 are cross sectional views illustrating a method of manufacturing a semiconductor device illustrated in FIG. 5, FIG. 15 is a plan view illustrating an overlay key illustrated in FIG. 14, and FIG. 16 is a flow chart illustrating a method of calibrating the overlay key illustrated in FIG. 15.

Referring to FIG. 6, a silicon substrate 200 divided into a chip region and a scribe lane region may be provided.

An isolation layer 202 may be formed in the silicon substrate 200 by a trench isolation process to define an active region and an isolation region of the silicon substrate 200 in the chip region.

A gate insulation layer 204 may be formed on the silicon substrate 200. A polysilicon layer pattern 206 may be formed on the gate insulation layer 204 in the chip region. A spacer 208 including silicon nitride may be formed on a sidewall of the polysilicon layer pattern 206. A portion of the silicon substrate 200 between the spacers 208 may be exposed.

A silicidation-blocking layer 213 may be formed on the polysilicon layer pattern 206 and the silicon substrate 200. The silicidation-blocking layer 213 may include a buffer oxide layer 210 and a silicon nitride layer 212 formed on the buffer oxide layer 210. The buffer oxide layer 210 may function to prevent stresses. Stress may be generated if the silicon nitride layer 212 is in direct contact with the silicon substrate 200.

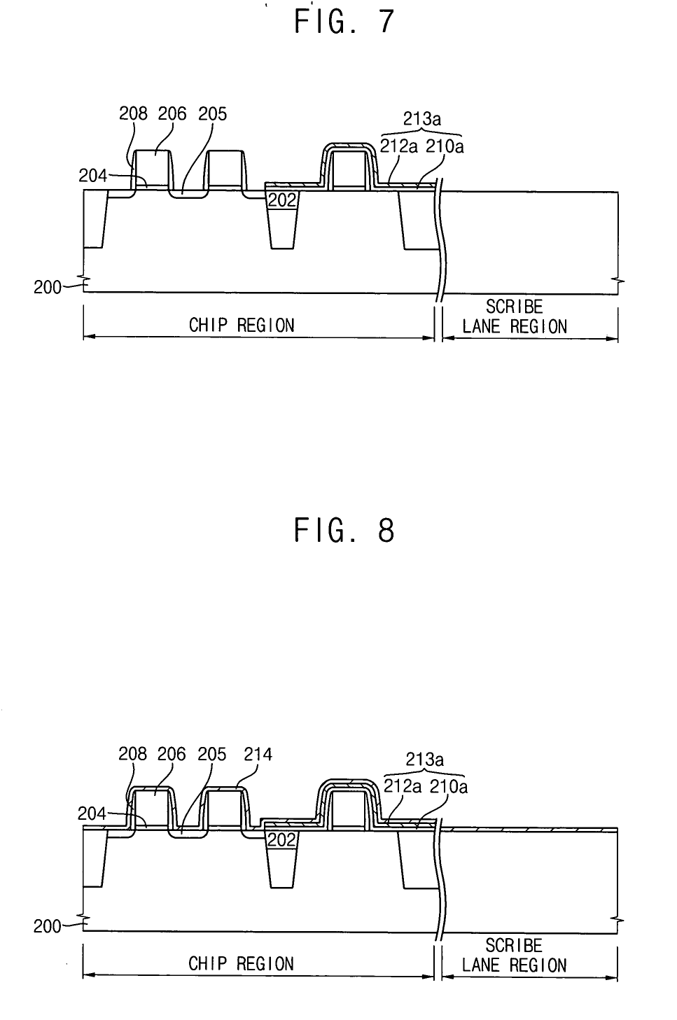

Referring to FIG. 7, the silicidation-blocking layer 213 may be partially etched to form a silicidation-blocking layer pattern 213a. The silicidation-blocking layer pattern 213a may selectively expose desired portions of upper surfaces of the polysilicon layer pattern 206 and the silicon substrate 200 in the chip region to be silicidated.

The silicidation-blocking layer pattern 213a may serve as a mask for selectively silicidating a specific transistor among a plurality of transistors that may be formed on the chip region. In a memory device, the silicidation-blocking layer pattern 213a functions as to silicidate a transistor included in a main cell and to prevent another transistor included in a peripheral circuit from being silicidated. Thus, the silicidation-blocking layer pattern 213a may not be formed on the silicon substrate 200 in the scribe lane region. As a result, the silicon substrate 200 in the scribe lane region may be exposed.

Referring to FIG. 8, a native oxide layer (not shown) on the silicon substrate 200 and the polysilicon layer pattern 206 may be removed.

A metal layer 214 may be formed on the silicon substrate 200, the polysilicon layer pattern 206, and the silicidation-blocking layer pattern 213a. The metal layer 214 may be converted into a metal silicide layer by a silicidation process. Examples of the metal layer 214 may include a cobalt layer, a tungsten layer, a titanium layer, a tantalum layer, etc. In FIG. 8, the cobalt layer may be used as the metal layer 214.

The higher a light reflexibility of the metal silicide layer, the more accurate the overlay calibration. The light reflexibility of the metal silicide layer means the quality or capacity of reflexing light. When a cobalt layer is used as the metal layer 214, the light absorption constant of the cobalt layer may be about 2.5% to about 4% to improve the light reflexibility of the cobalt silicide layer.

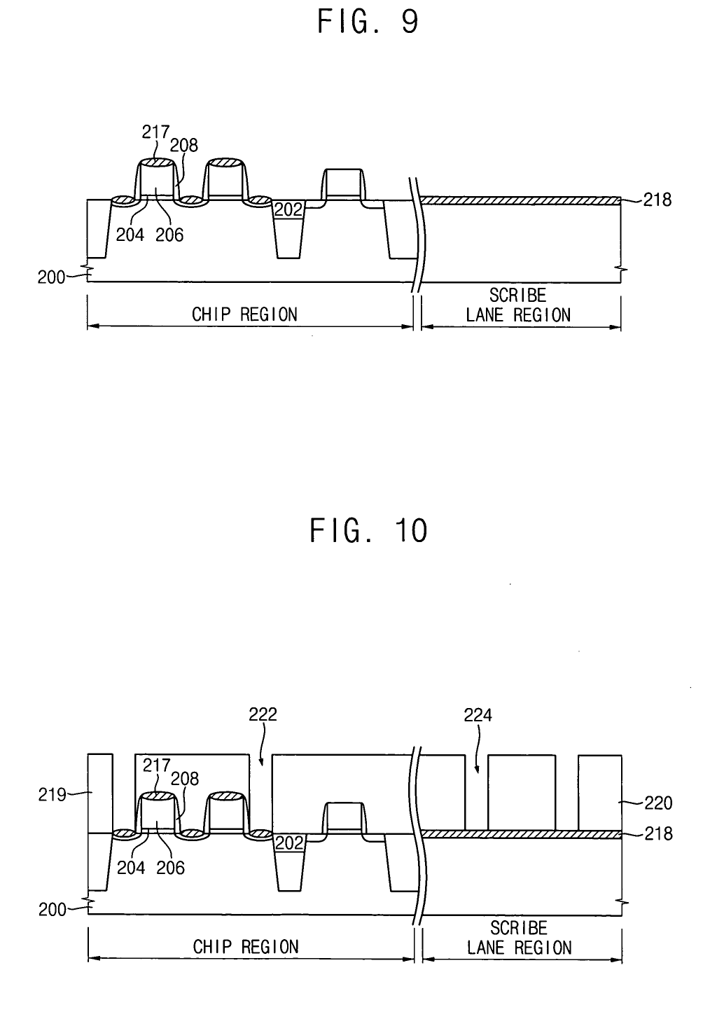

Referring to FIG. 9, the silicon substrate 200 may be primarily thermal treated. Metal in the metal layer 214, silicon in the silicon substrate 200 and polysilicon in the polysilicon layer pattern 206 may be reacted with each other to form a preliminary metal silicide layer (not shown) on the silicon substrate 200 and the polysilicon layer pattern 206.

The preliminary metal silicide layer may be secondarily thermal treated at a temperature higher than in the primary thermal treatment to form a first metal silicide layer pattern 217 on the chip region, and a second metal silicide layer pattern 218 on the scribe lane region. The first and second metal silicide layer patterns 217 and 218 may have a stable phase and low resistance compared to that of the preliminary metal silicide layer. Since the metal layer 214 may be converted into the first and second metal silicide layer patterns 217 and 218, the first and second metal silicide layer patterns 217 and 218 may include substantially the same material.

In an example embodiment of the present invention, when a cobalt layer is used as the metal layer 214 (see FIG. 8), the primary thermal treatment may correspond to a rapid thermal process that may be carried out at a temperature of about 400° C. to about 500° C. Cobalt in the cobalt layer may chemically react with silicon in the silicon substrate 200 during the primary thermal treatment to form CoSi. Further, the secondary thermal treatment may correspond to a rapid thermal process that may be carried out at a temperature of about 600° C. to about 900° C. The CoSi may be converted into CoSi₂ having a stable phase and low resistance.

Although the primary and secondary thermal treatments are performed, the metal layer 214 on the silicidation-blocking layer pattern 213 (see FIG. 8) and the spacer 208 may not be silicidated. Any non-reacted metal layer may be removed. The silicidation-blocking layer pattern 213a may also be removed.

Referring to FIG. 10, an insulation interlayer structure may be formed on the silicon substrate 200 including the first and second silicide layer patterns 217 and 218. The insulation interlayer structure may include a first insulation interlayer 219 on the chip region, and a second insulation interlayer 220 on the scribe lane region.

The first insulation interlayer 219 may sufficiently cover the transistor on the chip region. Further, the first and second insulation interlayers 219 and 220 may include a silicon oxide layer having a high light transmissivity.

The first and second insulation interlayer 219 and 220 may be partially etched to form a contact hole 222 exposing source/drain regions 216 in the chip region and a trench corresponding a lower overlay mark 224 in the scribe lane region. The lower overlay mark 224 may have a box shape or a bar shape.

Referring to FIG. 11, the contact hole 222 and the lower overlay mark 224 may be filled with a conductive layer. Examples of the conductive layer may include a doped polysilicon layer, a tungsten layer, an aluminum layer, a copper layer, a titanium layer, a tantalum layer, a titanium nitride layer, a tantalum nitride layer, etc. The conductive layer may include a metal having a low resistance, for example, a tungsten layer, an aluminum layer, a copper layer, etc.

In an example embodiment of the present example, the conductive layer may include first barrier metal layers 226 and 230 and tungsten layers 228 and 232. The first barrier metal layers 226 and 230 including titanium/titanium nitride may be formed on inner surfaces of the contact hole 222 and the lower overlay mark 224, respectively. The tungsten layers 228 and 232 may be formed on the first barrier metal layer 226 and 230 to fill the contact hole 222 and the lower overlay mark 224, respectively.

The conductive layer may be polished by a chemical mechanical polishing (CMP) process to form a contact plug 229 in the contact hole 222 and a conductive layer pattern 234 in the lower overlay mark 224.

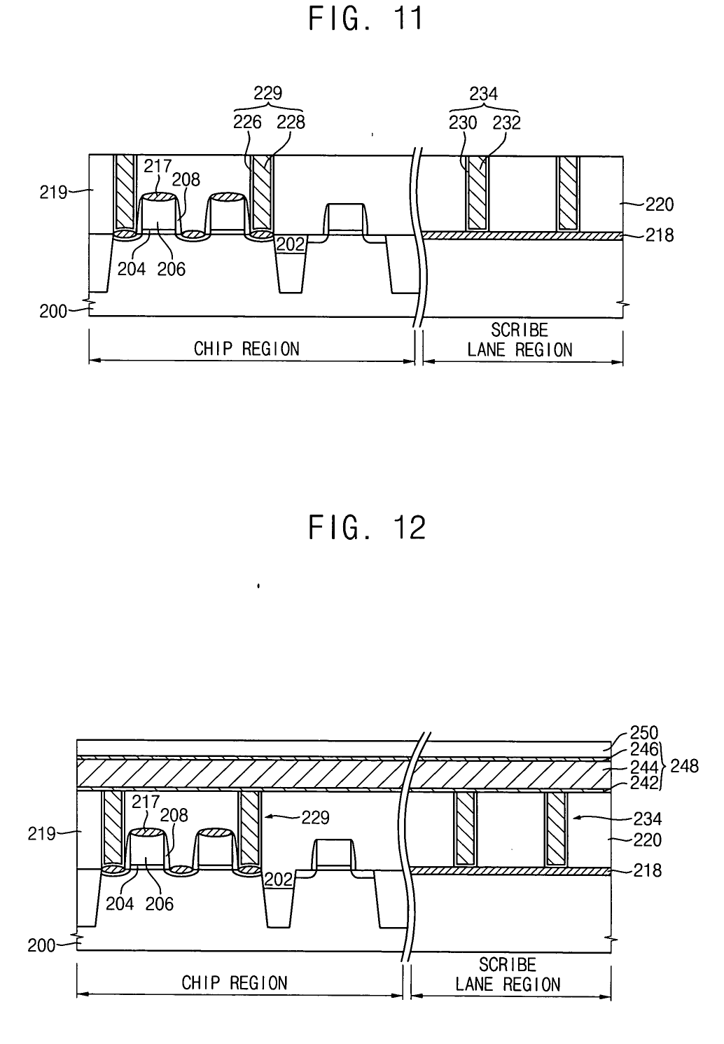

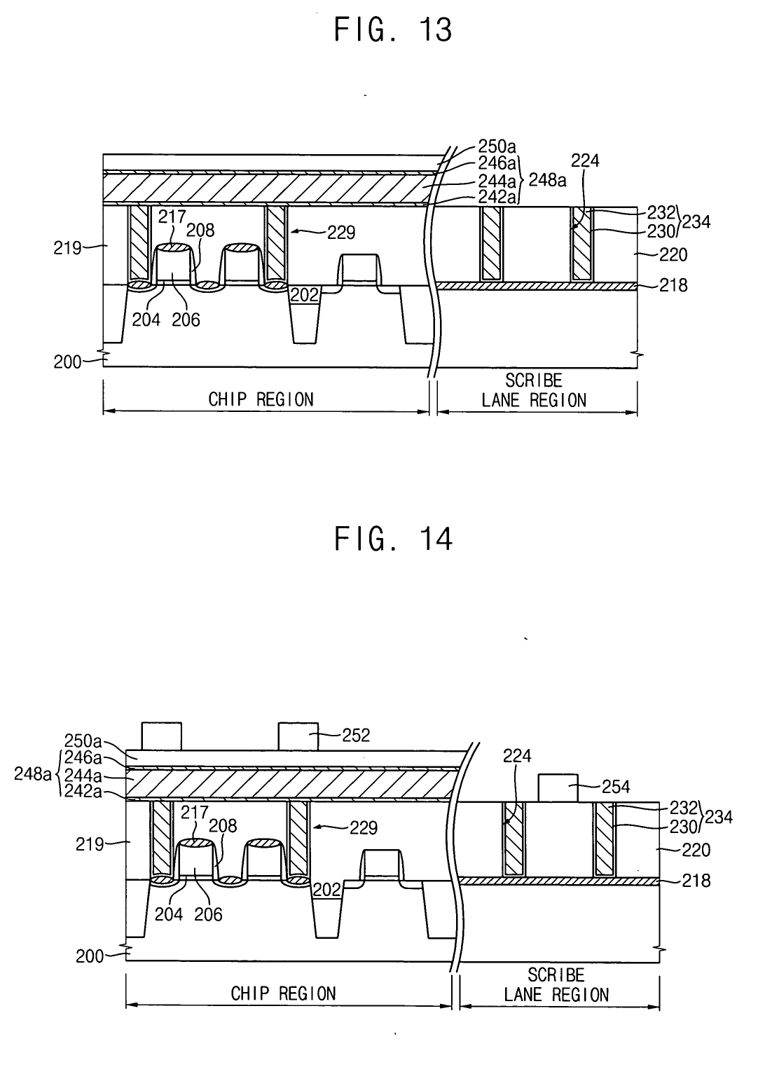

Referring to FIG. 12, a conductive layer 248 may be formed on the first and second insulation interlayers 219 and 220. Examples of the conductive layer 248 may include a tungsten layer, an aluminum layer, a copper layer, a titanium layer, a tantalum layer, a titanium nitride layer, a tantalum nitride layer, and in a combination thereof.

In an example embodiment of the present invention, the conductive layer 248 may include a sequentially stacked second barrier metal layer 242 for preventing metal atoms from diffusing into lower layers, an aluminum layer 244, and a third barrier metal layer 246. The second barrier metal layer 242 may include titanium nitride having a thickness of about 100 Å to about 300 Å. The aluminum layer 244 may have a thickness of about 1,000 Å to about 3,000 Å. The third barrier metal layer 246 may include titanium/titanium nitride having a thickness of about 100 Å to about 1,000 Å.

A hard mask layer 250 for patterning the conductive layer 248 may be formed on the conductive layer 248. Silicon nitride may be deposited by a chemical vapor deposition (CVD) process to form the hard mask layer 250. Optionally, an anti-reflective layer (not shown) including silicon oxynitride may be formed on the hard mask layer 250.

Referring to FIG. 13, the conductive layer 248 and the hard mask layer 250 may be selectively removed by a photolithography process to form a preliminary conductive layer pattern 248a and a preliminary hard mask layer pattern 250a. Simultaneously, a surface of the second insulation interlayer 220 having the lower overlay mark 224 in the scribe lane region may be exposed.

Referring to FIG. 14, a photoresist film (not shown) may be formed on the silicon substrate 200 in the chip region and the scribe lane region. The photoresist film may be exposed and developed to form a photoresist pattern 252 for forming an upper wiring on the chip region, and an upper overlay mark 254 in the scribe lane region. Particularly, the upper overlay mark 254 may be positioned on a central portion of the lower overlay mark 224.

Referring to FIG. 15, a lateral interval dx and a longitudinal interval dy between the lower overlay mark 224 and the upper overlay mark 254 on the scribe lane region may be measured to calibrate an overlay degree.

Hereinafter, a method of calibrating the overlay degree is illustrated in detail with reference to FIG. 16.

Referring to FIG. 16, in ST1, a sample substrate among a plurality of silicon substrate is chosen for calibration. A plurality of calibration regions where an overlay calibration is carried out is set on the sample substrate. A lateral interval and a longitudinal interval between a lower overlay mark and an upper overlay mark are measured to calibrate an overlay degree of each of the calibration regions.

In ST2, a misalignment degree of a photoresist pattern may be recognized based on the measured intervals.

In ST3, when the misalignment degree is outside an acceptable range, a misalignment-compensating data may be calculated. The misalignment may be corrected based on the misalignment-compensating data.

In ST4, the photoresist pattern may be completely removed, and a new photoresist pattern may be formed by a photolithography process.

A metal silicide layer having a high light reflexibility of about 8% to about 20% may be formed on a peripheral of the overlay key, for example, the silicon substrate in the scribe lane region. Thus, the peripheral of the overlay key may look bright so that accurate image information with respect to the lower overlay mark is obtained. As a result, the overlay calibration may be more accurate compared to a conventional overlay calibration.

On the contrary, when the misalignment degree is within an acceptable range, in ST5, subsequent processes may be performed on the sample substrate. A preliminary hard mask layer 250a may be etched using a photoresist pattern 252, which has been determined to be within an acceptable range, as an etching mask to form a hard mask layer pattern 250b. The conductive layer pattern 248a may be etched using the hard mask layer pattern 250b as an etching mask to form an upper wiring 248b electrically connected to the contact plug 229 in the chip region.

According to an example embodiment of the present invention, the overlay calibration may be relatively more accurate so that a failure caused by a misalignment in forming an upper wiring may be reduced. Further, a process to correct an overlay calibration is not required.

A semiconductor device of an example embodiment of the present example may include a transistor, a contact, and a metal wiring. Thus, example embodiments of the present invention may be used in a logic device, a memory device, an image sensor.

Forming Overlay Keys

Comparative Example 1

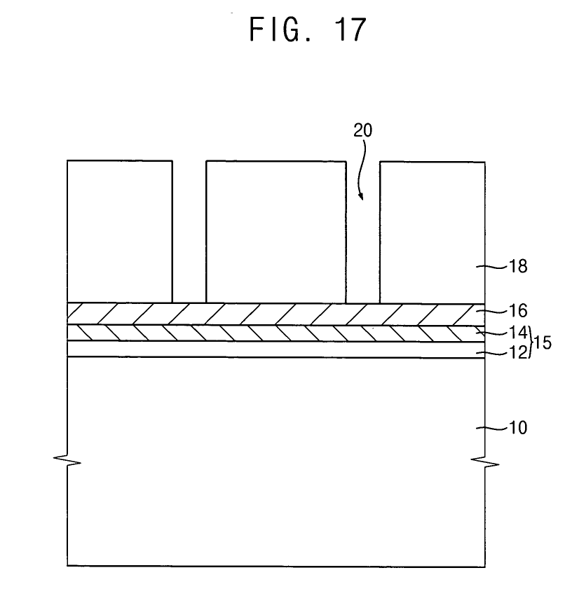

FIG. 17 is a cross sectional view illustrating an overlay key in accordance with Comparative Example 1.

Each sample in Comparative Example 1 was identically prepared, except for thicknesses of a silicon nitride layer and a silicon oxide layer.

Referring to FIG. 17, a silicon substrate 10 divided into a chip region and a scribe lane region was prepared.

A silicon oxide layer 12 and a silicon nitride layer 14, which may serve as a silicidation-blocking layer 15, were sequentially formed on the silicon substrate 10 in the scribe lane region.

As described above, the samples were distinguished from each other by thicknesses of the silicon oxide layer 12 and the silicon nitride layer 14. The silicon oxide layer 12 had a thickness of about 200 Å to about 2,000 Å, and the silicon nitride layer 14 had a thickness of about 200 Å to about 2,200 Å.

Table 1 below represents thicknesses of a silicon oxide layer and a silicon nitride layer in each of the samples. In Table 1, samples indicated by #1 had a substantially same thickness of about 200 Å; samples indicated by #2 had a substantially same thickness of about 400 Å; samples indicated by #3 had a substantially same thickness of about 600 Å, etc. On the contrary, samples in the group indicated by #1-1 to #1-10 had different silicon nitride layers thicknesses. For example, a silicon nitride layer of a sample indicated by #1-1 had a thickness of about 200 Å; a silicon nitride layer of a sample indicated by #1-2 had a thickness of about 400 Å; and, a silicon nitride layer of a sample indicated by #1-3 had a thickness of about 600 Å. As a result, one hundred samples were prepared by thicknesses of the silicon oxide layers and the silicon nitride layers in Comparative Example 1.

TABLE 1

| Thickness | Silicon oxide | −1 | −2 | −3 | −4 | −5 | −6 | −7 | −8 | −9 | −10 |
|---|---|---|---|---|---|---|---|---|---|---|---|
| (Å) | layer (fixed) | Silicon nitride layer | | | | | | | | | |
| #1 | 200 | 200 | 400 | 600 | 800 | 1000 | 1200 | 1400 | 1600 | 1800 | 2000 |
| #2 | 400 | 200 | 400 | 600 | 800 | 1000 | 1200 | 1400 | 1600 | 1800 | 2000 |
| #3 | 600 | 200 | 400 | 600 | 800 | 1000 | 1200 | 1400 | 1600 | 1800 | 2000 |
| #4 | 800 | 200 | 400 | 600 | 800 | 1000 | 1200 | 1400 | 1600 | 1800 | 2000 |
| #5 | 1000 | 200 | 400 | 600 | 800 | 1000 | 1200 | 1400 | 1600 | 1800 | 2000 |
| #6 | 1200 | 200 | 400 | 600 | 800 | 1000 | 1200 | 1400 | 1600 | 1800 | 2000 |
| #7 | 1400 | 200 | 400 | 600 | 800 | 1000 | 1200 | 1400 | 1600 | 1800 | 2000 |
| #8 | 1600 | 200 | 400 | 600 | 800 | 1000 | 1200 | 1400 | 1600 | 1800 | 2000 |
| #9 | 1800 | 200 | 400 | 600 | 800 | 1000 | 1200 | 1400 | 1600 | 1800 | 2000 |
| #10 | 2000 | 200 | 400 | 600 | 800 | 1000 | 1200 | 1400 | 1600 | 1800 | 2000 |

A cobalt layer 16 was formed on the silicidation-blocking layer 15. An insulation interlayer 18 having a thickness of about 4,000 Å to about 6,000 Å was formed on the cobalt layer 16. The insulation interlayer 18 may include a silicon oxide layer having a high light transmissivity.

A lower overlay mark 20 was provided to the insulation interlayer 18. The lower overlay mark 20 having a box shape corresponding to a trench by partially etching the insulation interlayer 18 was formed.

An anti-reflective layer (not shown) having a thickness of about 100 Å was formed on the lower overlay mark 20.

Forming an Overlay Key in Accordance with an Example Embodiment

Silicon substrates divided into a chip region and a scribe lane region were prepared. A cobalt silicide layer was formed on each of the silicon substrates in the scribe lane region. A cobalt layer and the silicon substrate were chemically reacted with each other to form the cobalt silicide layer.

Each of the cobalt layers of the one hundred eleven samples had different refractive indexes and light absorption constants as seen in Table 2. The refractive index was about 3 to about 5 and the light absorption constant was about 0.5% to about 2.5%.

Table 2 below represents the refractive indexes and the light absorption constants of the cobalt layers. In Table 2, cobalt layers in a group indicated by #1 had a substantially same light absorption constant of about 0.5; a group indicated by #2 had a substantially same light absorption constant of about 0.7; and a group indicated by #3 had a substantially same light absorption constant of about 0.9. On the contrary, the group indicated by from #1-1 to #1-10 had a light absorption constant of about 3 to about 5. For example, a cobalt layer of a sample indicated by #1-1had a light absorption constant of about 3; a cobalt layer of a sample indicated by #1-2 had a light absorption constant of about 3.2; and a cobalt layer of a sample indicated by #1-3 had a light absorption constant of about 3.4. As a result, one hundred eleven samples were prepared

TABLE 2

| | Light | | | | | | | | | | | |
|---|---|---|---|---|---|---|---|---|---|---|---|---|
| | absorp- | | | | | | | | | | | |
| | tion | | | | | | | | | | | |
| | constant | −1 | −2 | −3 | −4 | −5 | −6 | −7 | −8 | −9 | −10 | −11 |
| | (fixed) | Refractive index | | | | | | | | | | |
| #1 | 0.5 | 3.0 | 3.2 | 3.4 | 3.6 | 3.8 | 4.0 | 4.2 | 4.4 | 4.6 | 4.8 | 5.0 |
| #2 | 0.7 | 3.0 | 3.2 | 3.4 | 3.6 | 3.8 | 4.0 | 4.2 | 4.4 | 4.6 | 4.8 | 5.0 |
| #3 | 0.9 | 3.0 | 3.2 | 3.4 | 3.6 | 3.8 | 4.0 | 4.2 | 4.4 | 4.6 | 4.8 | 5.0 |
| #4 | 1.1 | 3.0 | 3.2 | 3.4 | 3.6 | 3.8 | 4.0 | 4.2 | 4.4 | 4.6 | 4.8 | 5.0 |
| #5 | 1.3 | 3.0 | 3.2 | 3.4 | 3.6 | 3.8 | 4.0 | 4.2 | 4.4 | 4.6 | 4.8 | 5.0 |
| #6 | 1.5 | 3.0 | 3.2 | 3.4 | 3.6 | 3.8 | 4.0 | 4.2 | 4.4 | 4.6 | 4.8 | 5.0 |
| #7 | 1.7 | 3.0 | 3.2 | 3.4 | 3.6 | 3.8 | 4.0 | 4.2 | 4.4 | 4.6 | 4.8 | 5.0 |
| #8 | 1.9 | 3.0 | 3.2 | 3.4 | 3.6 | 3.8 | 4.0 | 4.2 | 4.4 | 4.6 | 4.8 | 5.0 |
| #9 | 2.1 | 3.0 | 3.2 | 3.4 | 3.6 | 3.8 | 4.0 | 4.2 | 4.4 | 4.6 | 4.8 | 5.0 |
| #10 | 2.3 | 3.0 | 3.2 | 3.4 | 3.6 | 3.8 | 4.0 | 4.2 | 4.4 | 4.6 | 4.8 | 5.0 |
| #11 | 2.5 | 3.0 | 3.2 | 3.4 | 3.6 | 3.8 | 4.0 | 4.2 | 4.4 | 4.6 | 4.8 | 5.0 |

by the refractive indexes and the light absorption constants of the cobalt layers.

An insulation interlayer having a thickness of about 4,000 Å to about 6,000 Å was formed on the cobalt silicide layer. The insulation interlayer included a silicon oxide layer having a high light transmissivity.

A lower overlay mark was provided to the insulation interlayer. The lower overlay mark having a box shape corresponding to a trench that was formed by partially etching the insulation interlayer.

An anti-reflective layer (not shown) having a thickness of about 100 Å was formed on the lower overlay mark.

Comparing Light Reflexibility of the Overlay Keys

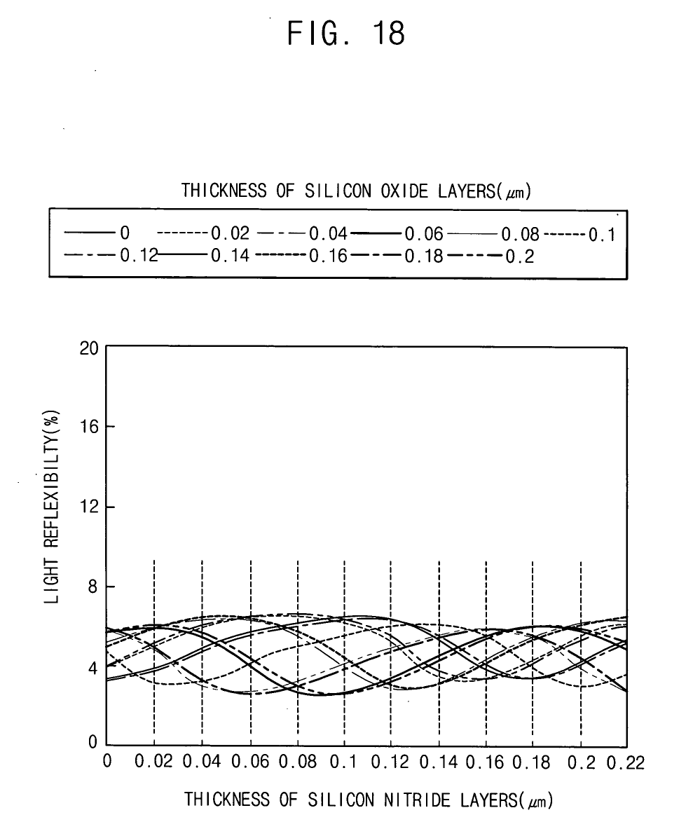

FIG. 18 is a graph illustrating light reflexibility of the overlay key illustrated in FIG. 17 by thicknesses of a silicon oxide layer and a silicon nitride layer.

As shown in FIG. 18, the overlay key of Comparative Example in FIG. 17 has light reflexibility slightly different from each other by the thicknesses of the silicon oxide layers and the silicon nitride layers. The overlay key of Comparative Example has a light reflexibility of about 2% to about 6%.

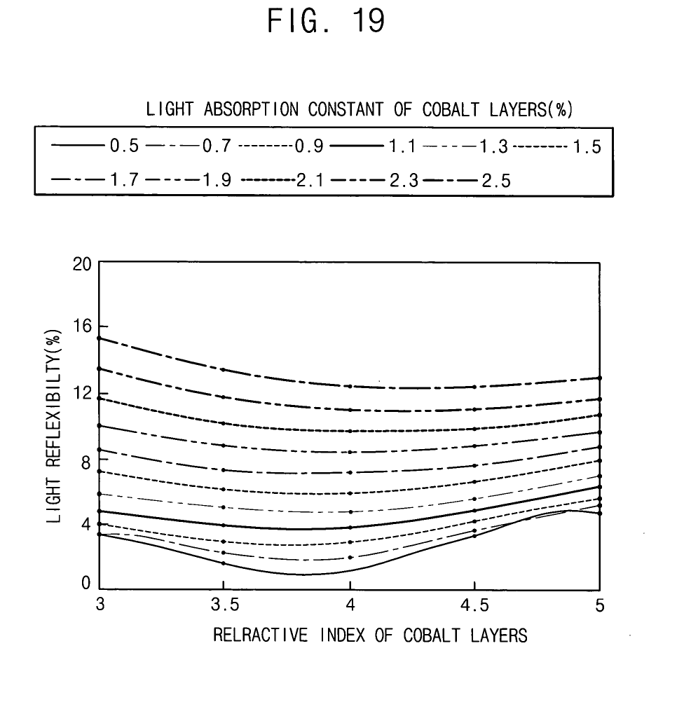

FIG. 19 is a graph illustrating light reflexibility of the overlay key illustrated in FIG. 1 by a refractive index and a light absorption constant of cobalt that is converted into a cobalt silicide layer.

As shown in FIG. 19, it can be noted that the light reflexibility of the overlay key is predominantly dependent on the light absorption constant of the cobalt layer. The overlay key has a light reflexibility of no less than about 15% by optimizing the refractive index and the light absorption constant of the cobalt layer. Further, to obtain an improved light reflexibility compared to that of a conventional overlay key, it can be noted that the light absorption constant of the cobalt layer is no less than about 1.5%.

Comparing Between Images of the Overlay Keys

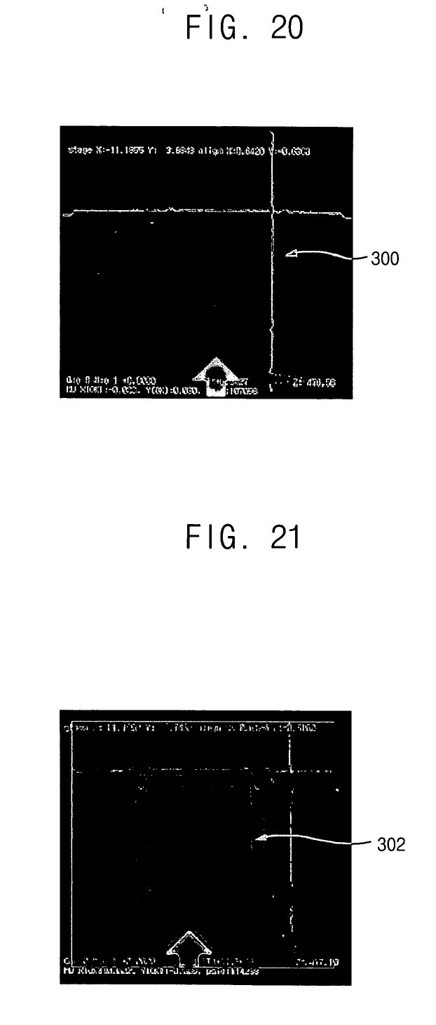

FIG. 20 is a scanning electron microscope (SEM) image illustrating the overlay key illustrated in FIG. 17, and FIG. 21 is an SEM image illustrating the overlay key illustrated in FIG. 1.

As shown in FIG. 20, since a stacked structure including a silicon oxide layer, a silicon nitride layer and a cobalt layer may be formed at a peripheral of the conventional overlay key, the overlay key has a very low light reflexibility. Thus, the peripheral of the conventional overlay key may look dark. As a result, it is very difficult to distinguish a lower overlay mark.

On the contrary, as shown in FIG. 21, since a silicide layer may be formed at a peripheral of the overlay key in accordance with example embodiments of the present invention, the overlay key looks bright so that a lower overlay mark may be distinctly distinguished.

According to example embodiments of the present invention, a layer having a high light reflexibility may be formed beneath a lower overlay mark. Thus, accurate image information with respect to the overlay key may be obtained so that overlay calibration may be accurate and reproducibility of the overlay calibration may be very high. As a result, an overlay variation of the substrates may be reduced so that failures, for example, misalignment between overlapped layers may be reduced during a photolithography process. Further, an unnecessary process to correct the overlay calibration may not be required.

Having described example embodiments of the present invention, it is noted that modifications and variations may be made by a person skilled in the art in light of the above teachings. It is therefore to be understood that changes may be made in the particular example embodiments of the present invention disclosed which is within the scope of the present invention.

What is claimed is:

1. An overlay key formed in a scribe lane region and used to align a circuit pattern comprising a lower overlay mark formed on a first metal silicide layer directly in contact with a silicon substrate.

2. The overlay key of claim 1, further including an upper overlay mark formed above the lower overlay mark.

3. The overlay key of claim 1, wherein the first metal silicide layer includes at least one layer selected from the group consisting of a cobalt silicide layer, a tungsten silicide layer, a titanium silicide layer, and a tantalum silicide layer.

4. The overlay key of claim 1, wherein the first metal silicide layer has a light reflexibility of about 8% to about 30%.

5. A semiconductor device comprising:
a semiconductor structure formed on a chip region, the semiconductor structure including a transistor having a second metal silicide layer, an insulation interlayer, and an upper wiring; and
the overlay key of claim 1.

6. The semiconductor device of claim 5, wherein a material of the first and second metal silicide layers is the same.

7. The semiconductor device of claim 5, wherein the first metal silicide layer includes a layer selected from a group consisting of a cobalt silicide layer, a tungsten silicide layer, a titanium silicide layer, and a tantalum silicide layer.

8. The semiconductor device of claim 7, wherein the first metal silicide layer has a light reflexibility of about 8% to about 30%.

9. The semiconductor device of claim 7, further including an upper overlay mark formed on the lower overlay mark.

10. A method of forming an overlay key in a scribe lane region, comprising:
providing a silicon substrate;
forming a first metal silicide layer in direct contact with the silicon substrate; and
forming a lower overlay mark on the first metal silicide layer.

11. The method of claim 10, further including forming an upper overlay mark on the lower overlay mark.

12. The method of claim 10, wherein forming the first metal silicide layer includes: forming a metal layer on the silicon substrate; and
thermally treating the silicon substrate and the metal layer to chemically react silicon in the silicon substrate with metal in the metal layer.

13. The method of claim 12, wherein the metal layer includes at least one layer consisting of a cobalt layer, a tungsten layer, a titanium layer, and a tantalum layer.

14. The method of claim 12, wherein the metal layer has a light absorption constant of about 1.5% to about 4%.

15. A method of manufacturing a semiconductor device, comprising:
forming a transistor having a second metal silicide layer on the silicon substrate in a chip region;
forming an overlay key according to claim 10;
forming an insulation interlayer on the transistor;
partially etching the insulation interlayer in the scribe lane region to form the lower overlay mark, wherein the lower overlay mark is trench-shaped;
forming a conductive layer on the chip region and the scribe lane region;
forming a photoresist pattern on the conductive layer in the chip region, and an upper overlay mark on the silicon substrate in the scribe lane region; and
partially etching the conductive layer using the photoresist pattern as an etching mask to form an upper wiring.

16. The method of claim 15, wherein forming the transistor and the first metal silicide layer comprises:
sequentially forming a gate insulation layer and a polysilicon layer pattern on the silicon substrate;
forming a silicidation-blocking layer pattern on the polysilicon layer pattern and the silicon substrate, the silicidation-blocking layer pattern partially exposing surfaces of the polysilicon layer pattern and the silicon substrate in the chip region and wholly exposing the silicon substrate in the scribe lane region;
forming a metal layer on the polysilicon layer pattern, the silicon substrate and the silicidation-blocking layer pattern; and
reacting the metal layer, the silicon substrate, and the polysilicon layer pattern.

17. The method of claim 16, wherein the metal layer includes at least one layer selected from the group consisting of a cobalt layer, a tungsten layer, a titanium layer, and a tantalum layer.

18. The method of claim 16, wherein the metal layer has a light absorption constant of about 1.5% to about 4%.

19. The method of claim 15, further including forming a contact hole in the chip region, the contact hole being formed simultaneously with the lower overlay mark.

20. The method of claim 19, further including depositing a conductive material on inner surfaces of the trench-shaped lower overlay mark and the contact hole.

21. The method of claim 15, wherein the conductive layer includes at least one layer selected from a group consisting of a metal layer and a metal nitride layer.

22. The method of claim 15, further including forming an upper overlay mark on the lower overlay mark.
